(19) United States
(12) Patent Application Publication
(10) Pub. No.: US 2024/0243111 A1
(43) Pub. Date: Jul. 18, 2024

(54) SEMICONDUCTOR PACKAGE

(71) Applicant: SAMSUNG ELECTRONICS CO., LTD., Suwon-si (KR)

(72) Inventors: Chajea JO, Suwon-si (KR); Dohyun KIM, Suwon-si (KR); SeungRyong OH, Suwon-si (KR)

(21) Appl. No.: 18/489,493

(22) Filed: Oct. 18, 2023

(30) Foreign Application Priority Data
Jan. 13, 2023 (KR) 10-2023-0005582

(51) Int. Cl. H01L 25/10; H01L 23/00; H01L 23/31; H01L 23/48; H01L 23/498; H01L 23/522; H01L 25/065

(52) U.S. Cl. CPC H01L 25/105; H01L 23/3128; H01L 23/481; H01L 23/49822; H01L 23/5226; H01L 24/16; H01L 25/0657; H01L 24/17; H01L 24/30; H01L 24/32; H01L 24/48; H01L 24/73; H01L 2224/16145; H01L 2224/16227; H01L 2224/17181; H01L 2224/30181; H01L 2224/32145; H01L 2224/32225; H01L 2224/48227; H01L 2224/73204; H01L 2224/73253

(57) ABSTRACT

A semiconductor package includes a lower package and an upper package on the lower package. The lower package includes a first substrate, chip stacks on the first substrate, a first mold structure on the first substrate that covers the chip stacks, and a second substrate on the first mold structure. The chip stacks include a first semiconductor chip and a second semiconductor chip on the first semiconductor chip. The first semiconductor chip includes a first semiconductor substrate, a first wiring layer adjacent the first semiconductor substrate and including wiring patterns, a first circuit layer on the first semiconductor substrate and including a transistor and circuit wirings connected to the transistor, and a chip through electrode penetrating at least a portion of the first circuit layer and the first semiconductor substrate and a height of the chip through electrode ranges from 2 μm to 50 μm.

### CROSS-REFERENCE TO RELATED APPLICATIONS

This U.S. non-provisional patent application claims priority under 35 U.S.C. § 119 to Korean Patent Application No. 10-2023-0005582, filed on Jan. 13, 2023 in the Korean Intellectual Property Office, the disclosure of which is hereby incorporated by reference in its entirety.

### BACKGROUND OF THE INVENTION

The present disclosure relates to semiconductor packages and methods of manufacturing the same.

A semiconductor package is provided to implement an integrated circuit chip to qualify for use in electronic products. Typically, a semiconductor package includes a semiconductor chip mounted on a printed circuit board (PCB) and bonding wires or bumps that electrically connect the semiconductor chip to the printed circuit board. With the development of electronic industry, various research has been conducted to improve reliability, to have high integration, and to reduce sizes of semiconductor packages.

### SUMMARY

An object of the present disclosure is to provide a structure of a semiconductor package with improved electrical characteristics.

The problem to be solved by the present disclosure is not limited to the problems mentioned above, and other problems not mentioned will be clearly understood by those skilled in the art from the description below.

A semiconductor package according to some embodiments of the present disclosure may include a lower package, and an upper package on the lower package, wherein the lower package may include a first substrate, chip stacks on the first substrate, a first mold structure on the first substrate and covering at least a portion of the chip stacks, and a second substrate on the first mold structure. The chip stacks may include a first semiconductor chip and a second semiconductor chip on the first semiconductor chip, the first semiconductor chip may include a first semiconductor substrate, a first wiring layer adjacent the first semiconductor substrate and including wiring patterns, a first circuit layer on the first semiconductor substrate and including a transistor and circuit wirings connected to the transistor, and a chip through electrode penetrating at least a portion of the first circuit layer and the first semiconductor substrate. A height of the chip through electrode may range from 2 μm to 50 μm, a width of the first semiconductor chip may be substantially equal to a width of the second semiconductor chip, and the chip through electrode may be connected to the wiring patterns and the circuit wirings.

A semiconductor package according to some embodiments of the present disclosure may include a first semiconductor chip and a second semiconductor chip on the first semiconductor chip. The first semiconductor chip may include a first wiring layer including a plurality of first wiring patterns, a first circuit layer on the first wiring layer, the first circuit layer including a plurality of first transistors, a plurality of first circuit wirings connected to the plurality of first transistors, a plurality of first power pads connected to the first transistors, and a plurality of circuit upper pads on the first circuit layer. A first semiconductor substrate is interposed between the first wiring layer and the first circuit layer, and a first chip through electrode penetrates the first semiconductor substrate and is connected to the plurality of first wiring patterns and to the plurality of first power pads. The second semiconductor chip may include a second semiconductor substrate, a second wiring layer adjacent the second semiconductor substrate, the second wiring layer including a plurality of wiring pads provided on a lower surface of the second wiring layer, and a plurality of second wiring patterns connected to the plurality of wiring pads. A second circuit layer is on the second semiconductor substrate, the second circuit layer including a plurality of second transistors, a plurality of second circuit wirings connected to the plurality of second transistors, and a plurality of second power pads. A second chip through electrode penetrates the second semiconductor substrate and is connected to the plurality of second wiring patterns and the plurality of second power pads. The plurality of circuit upper pads and the plurality of wiring pads may be in direct contact with each other. A thickness of the first semiconductor chip may be substantially equal to a thickness of the second semiconductor chip.

A semiconductor package according to some embodiments of the present disclosure may include a first substrate, a plurality of chip stacks on the first substrate, a conductive post on the first substrate and spaced apart from the plurality of chip stacks in a first direction. A mold structure covers the conductive post and the plurality of chip stacks, and a second substrate is on the mold structure. The plurality of chip stacks include a first semiconductor chip and a second semiconductor chip on the first semiconductor chip. The first semiconductor chip may include a wiring layer, a circuit layer on the wiring layer, a semiconductor substrate interposed between the wiring layer and the circuit layer, and a chip through electrode penetrating the semiconductor substrate. The wiring layer may include a wiring insulation layer and a plurality of wiring patterns in the wiring insulating layer. The circuit layer may include a first circuit insulating layer, a plurality of transistors in the first circuit insulating layer, a second circuit insulating layer on the first circuit insulating layer, a plurality of first circuit wirings in the second circuit insulating layer, and a power pad on a lower surface of the second circuit insulating layer that contacts the chip through electrode. The chip through electrode may penetrate the first circuit insulating layer. The chip through electrode may have a first height. A vertical height from an upper surface of the first circuit insulating layer to an upper surface of the wiring insulating layer may be a second height, and the first height may have a range of 2 μm to 50 μm.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to embodiments of the present disclosure.

FIG. 2 is a cross-sectional view taken along line A-A′ of FIG. 1.

FIG. 3 is an enlarged view of chip stacks according to embodiments of the present disclosure.

FIG. 4 is an enlarged view of chip stacks according to other embodiments of the present disclosure.

FIGS. 5A to 5C are cross-sectional views illustrating a method of manufacturing chip stacks according to embodiments of the present disclosure.

FIGS. 6A to 6I are cross-sectional views illustrating a method of manufacturing a semiconductor package according to embodiments of the present disclosure.

FIG. 7 is a cross-sectional view of a semiconductor package according to other embodiments of the present disclosure.

### DETAILED DESCRIPTION

Hereinafter, semiconductor packages and methods of manufacturing the same according to the concept of the present disclosure will be described with reference to the drawings.

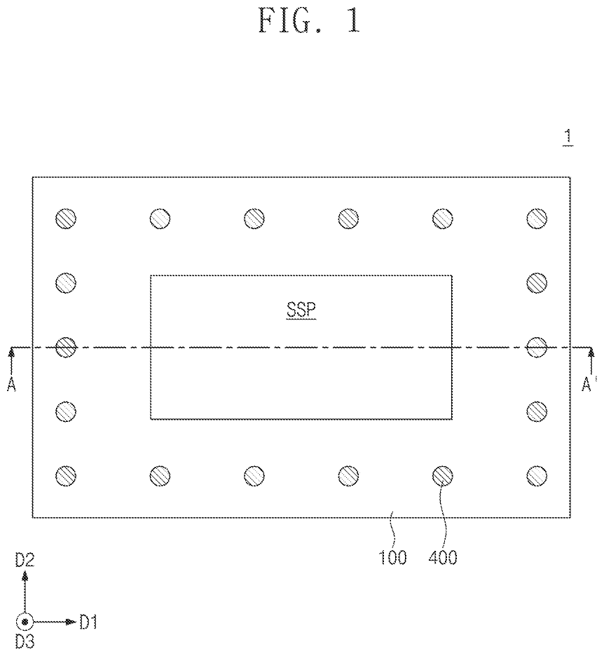

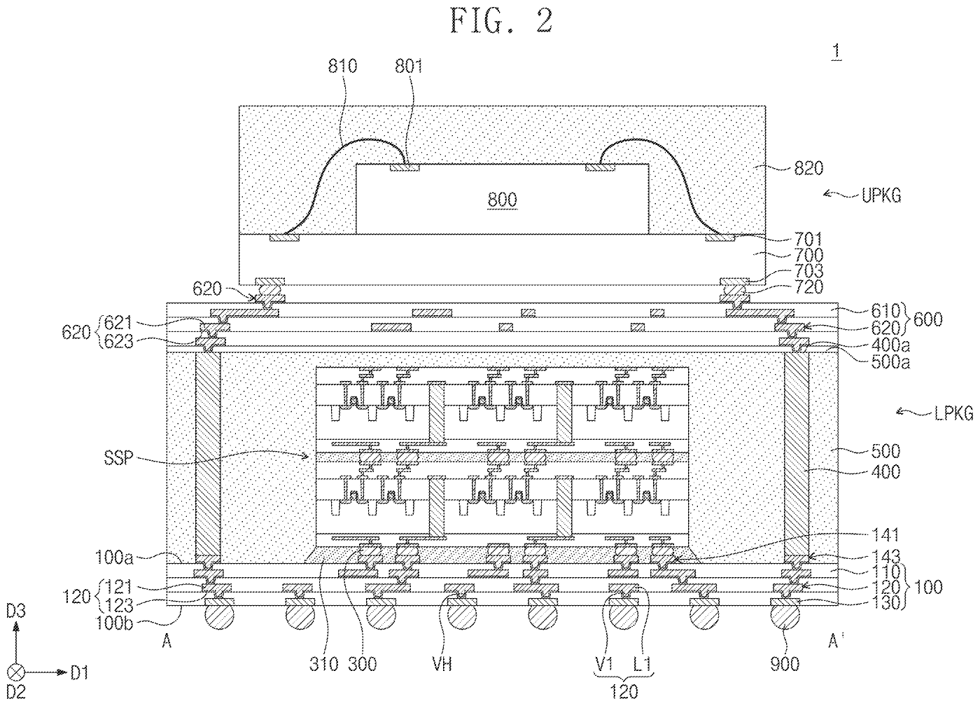

FIG. 1 is a plan view of a semiconductor package according to embodiments of the present disclosure. FIG. 2 is a cross-sectional view taken along line A-A′ of FIG. 1.

Referring to FIGS. 1 and 2, a semiconductor package 1 may include a lower package LPKG and an upper package UPKG on the lower package LPKG. The semiconductor package 1 may have a package on package structure.

The lower package LPKG may include a first substrate 100, chip stacks SSP, conductive posts 400, a first mold structure 500, and a second substrate 600. The first substrate 100 and the second substrate 600 may also be referred to as a lower substrate 100 and an upper substrate 600, respectively.

The first substrate 100 may have a first surface 100a and a second surface 100b opposite to each other. A direction parallel to the first surface 100a of the first substrate 100 is defined as a first direction D1. A direction parallel to the first surface 100a and perpendicular to the first direction D1 is defined as a second direction D2. A direction perpendicular to the first surface 100a of the first substrate 100 is defined as a third direction D3.

The first substrate 100 may be a printed circuit board (PCB) or a redistribution board.

When the first substrate 100 is a redistribution substrate, as shown in FIG. 2, the first substrate 100 may include first insulating layers 110, first redistribution patterns 120, and under bump patterns 130. The first redistribution patterns 120 and the under bump patterns 130 may be disposed in the first insulating layers 110. Unlike the drawing, the first insulating layers 110 may be observed as one insulating layer. The first insulating layer 110 may include a photosensitive insulating material. For example, the first insulating layer 110 may include at least one of photosensitive polyimide, polybenzoxazole, phenol-based polymer, and benzocyclobutene-based polymer.

The under bump patterns 130 may be disposed on the second surface 100b of the first substrate 100. Lower surfaces of each of the under bump patterns 130 may be exposed at the first insulating layer 110, as illustrated in FIG. 2. The under bump patterns 130 may include copper or aluminum.

The first redistribution patterns 120 may be stacked and disposed on the under bump patterns 130. Each of the first redistribution patterns 120 may include a first conductive pattern 121 and a first seed/barrier pattern 123. For example, the first conductive pattern 121 may include copper, and the first seed/barrier pattern 123 may include copper and titanium.

The first seed/barrier pattern 123 may be locally provided on a lower surface of the first conductive pattern 121. Each of the first redistribution patterns 120 may include a via part V1 and a wiring part LI integrally connected thereto. The via part V1 of the first redistribution pattern 120 may fill a via hole VH of the first insulating layer 110, and may be connected to the wiring part LI of the other first redistribution pattern 120 therebelow or the under bump pattern 130.

First upper pads 141 and second upper pads 143 may be provided on an uppermost first redistribution pattern 120 among the first redistribution patterns 120. The first upper pads 141 and the second upper pads 143 may have substantially the same structure as the first redistribution patterns 120. That is, the first upper pad 141 and the second upper pad 143 may include a first conductive pattern 121 and a first seed/barrier pattern 123, respectively.

The chip stacks SSP may be provided on the first substrate 100. The chip stacks SSP may include a first semiconductor chip 200a to be described later and a second semiconductor chip 200b to be described later.

A first connection terminal 300 may be interposed between the first upper pad 141 and the chip stacks SSP. The first connection terminal 300 may be electrically connected to the first upper pad 141 and the chip stacks SSP. The chip stacks SSP may be electrically connected to the first substrate 100 through the first connection terminal 300. The first connection terminal 300 may include at least one of a solder, a pillar, and a bump. The first connection terminal 300 may include a conductive material such as tin (Sn) or silver (Ag).

A first underfill pattern 310 may be interposed between the lower surfaces of the chip stacks SSP and the first surface 100a of the first substrate 100. The first underfill pattern 310 may cover a side surface of the first connection terminal 300. According to some embodiments, the first underfill pattern 310 may be omitted. In this case, the first mold structure 500, to be described later, may fill a space between the chip stacks SSP and the first substrate 100 and may cover a side surface of the first connection terminal 300. The first underfill pattern 310 may include insulating resin.

The conductive posts 400 may be disposed on the first surface 100a of the first substrate 100 and spaced apart from side surfaces of the chip stacks SSP. Each of the conductive posts 400 may vertically overlap a corresponding one of the second upper pads 143. When viewed in a plan view, the plurality of conductive posts 400 may surround the chip stacks SSP, as illustrated in FIG. 1. An upper surface 400a of each of the conductive posts 400 may be higher than or at the same level as an upper surface of the chip stacks SSP. The conductive post 400 may include a metal material such as copper.

The first mold structure 500 may be disposed on the first surface 100a of the first substrate 100. The first mold structure 500 may cover at least a portion of the first surface 100a of the first substrate 100. The first mold structure 500 may cover at least a portion of each of the second upper pads 143. The first mold structure 500 may cover upper and side surfaces of the chip stacks SSP. The first mold structure 500 may cover side surfaces of the conductive posts 400. An upper surface 500a of the first mold structure 500 may be higher than or at the same level as the upper surface of the chip stacks SSP. The upper surface 500a of the first mold structure 500 may be at the same level as the upper surface 400a of each of the conductive posts 400. A side surface of the first mold structure 500 may be aligned with a side surface of the first substrate 100. The first mold structure 500 may include an epoxy molding compound (EMC).

The second substrate 600 may be disposed on the upper surface 500a of the first mold structure 500 and the upper surfaces 400a of the conductive posts 400. The second substrate 600 may be a redistribution substrate.

The second substrate 600 may include a second insulating layer 610 and a second redistribution pattern 620. The second insulating layer 610 may be a photosensitive insulating layer identical to or similar to that of the first insulating layer 110. The second redistribution pattern 620 may include a second conductive pattern 621 and a second seed/barrier pattern 623. The second conductive pattern 621 and the second seed/barrier pattern 623 may include the same or similar material as those of the first conductive pattern 121 and the first seed/barrier pattern 123, respectively. Like the first redistribution pattern 120, the second redistribution pattern 620 may have a via part V1 and a wiring part LI connected thereto.

The upper package UPKG may be provided on the second substrate 600. The upper package UPKG may include a package substrate 700, a third semiconductor chip 800, and a second mold structure 820. The package substrate 700 may be a printed circuit board or a redistribution board. Metal pads 701 and 703 may be provided on both sides of the package substrate 700. The third semiconductor chip 800 may be, for example, a memory chip or a logic chip. For example, a chip pad 801 disposed on one surface of the third semiconductor chip 800 may be connected to the metal pad 703 of the package substrate 700 by a bonding wire manner. The second mold structure 820 may include an epoxy molding compound (EMC).

An external connection terminal 900 may be provided below the first substrate 100. The external connection terminal 900 may be provided on a lower surface of the under bump pattern 130. The external connection terminal 900 may be in contact with the under bump pattern 130 and be electrically connected to the under bump pattern 130.

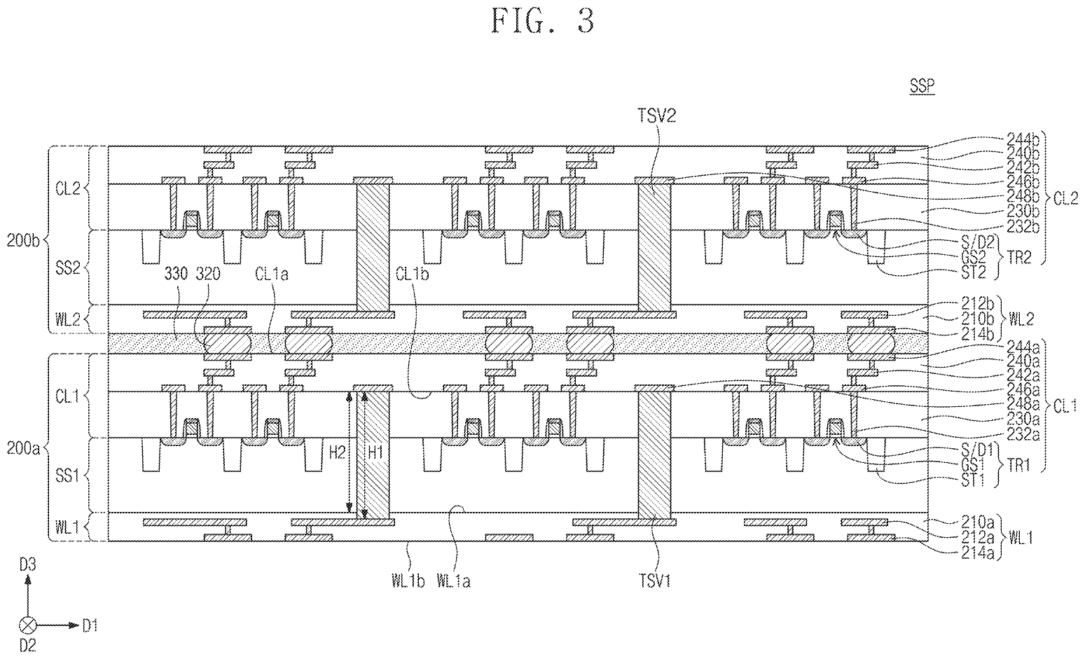

FIG. 3 is an enlarged view of chip stacks according to embodiments of the present disclosure.

Referring to FIGS. 2 and 3, the chip stacks SSP include a first semiconductor chip 200a, a second semiconductor chip 200b, second connection terminals 320, and a second underfill pattern 330. Although the chip stacks SSP are illustrated as including only two semiconductor chips in FIG. 2, the chip stacks SSP may include three or more semiconductor chip stacks. Various numbers of chip stacks may be utilized, depending on a design of the semiconductor package 1 to be implemented.

The first semiconductor chip 200a may include a first wiring layer WL1, a first semiconductor substrate SS1, a first circuit layer CL1, and first chip through electrodes TSV1. The first semiconductor chip 200a may be, for example, a logic chip or a memory chip such as DRAM or NAND flash.

The first wiring layer WL1 may include a first wiring insulating layer 210a, first wiring patterns 212a, and first wiring pads 214a. The first wiring patterns 212a and the first wiring pads 214a may be disposed in the first wiring insulating layer 210a. Unlike the drawing, the first insulating layers 110 may be formed of a plurality of layers. The first insulating layer 110 may include an insulating material such as silicon oxide, silicon nitride, or silicon oxynitride.

The first wiring layer WL1 may have a third surface WL1a and a fourth surface WL1b opposite to each other. The first wiring pads 214a may be disposed on the fourth surface WL1b of the first wiring layer WL1. A lower surface of each of the first wiring pads 214a may be exposed at the first wiring insulating layer 210a, as illustrated in FIG. 3. The first wiring pads 214a may include copper or aluminum.

The first wiring patterns 212a may be stacked and disposed on the first wiring pads 214a. The first wiring patterns 212a may correspond to redistribution patterns. The first wiring patterns 212a may include a metal material such as copper.

The first semiconductor substrate SS1 may be provided on the first wiring layer WL1. The first semiconductor substrate SS1 may be, for example, a silicon substrate, a germanium substrate, or a silicon-germanium substrate.

The first circuit layer CL1 may be disposed on the first semiconductor substrate SS1. The first circuit layer CL1 may have a fifth surface CL1a and a sixth surface CL1b opposite to each other. The first circuit layer CL1 may include a plurality of first integrated circuits, a first circuit insulating layer 230a, a plurality of first circuit plugs 232a, a second circuit insulating layer 240a, a plurality of first circuit wirings 242a, a plurality of first circuit upper pads 244a, a plurality of first circuit lower pads 246a, and a plurality of first power pads 248a.

The first integrated circuits may include a plurality of first transistors TR1 formed on the first semiconductor substrate SS1. The first transistors TR1 may include, for example, a metal-oxide-semiconductor field effect transistor (MOSFET), a system large scale integration (LSI), a micro-electro-mechanical system (MEMS), an active element, a passive element, and the like. When the first transistors TR1 are MOSFETs, the first transistors TR1 may include a first gate structure GS1, a first source/drain S/D1, and a first device isolation layer ST1.

The first circuit insulating layer 230a may be disposed on the first semiconductor substrate SS1 to cover at least a portion of the first transistors TR1. Unlike the drawing, the first circuit insulating layer 230a may be formed of a plurality of layers. The first circuit insulating layer 230a may include an insulating material such as silicon oxide, silicon nitride, or silicon oxynitride.

The first circuit plugs 232a may pass through the first circuit insulating layer 230a. The first circuit plugs 232a may be electrically connected to the first source/drain S/D1 and the first circuit lower pad 246a to be described later. The first circuit plugs 232a may include a metal material such as copper or tungsten.

A second circuit insulating layer 240a may be disposed on the first circuit insulating layer 230a. Unlike the drawing, the second circuit insulating layer 240a may be formed of a plurality of layers. The second circuit insulating layer 240a may include an insulating material such as silicon oxide, silicon nitride, or silicon oxynitride.

The first circuit wirings 242a may be disposed in the second circuit insulating layer 240a. The first circuit wirings 242a may correspond to a metal wiring layer. The first circuit wirings 242a may be electrically connected to the first circuit upper pads 244a, the first circuit lower pads 246a, and the first power pads 248a, which will be described later. The first circuit wirings 242a may include at least one of copper, aluminum, titanium, and tungsten.

The first circuit upper pads 244a may be disposed on the fifth surface CL1a of the second circuit insulating layer 240a. An upper surface of each of the first circuit upper pads 244a may be exposed at the second circuit insulating layer 240a, as illustrated in FIG. 3. The first circuit upper pads 244a may include a metal material such as copper or aluminum.

The first circuit lower pads 246a may be disposed on the sixth surface CL1b of the second circuit insulating layer 240a. A lower surface of each of the first circuit lower pads 246a may be exposed at the second circuit insulating layer 240a, as illustrated in FIG. 3. The first circuit lower pads 246a may include a metal material such as aluminum.

The first transistors TR1 may be electrically connected to the first circuit upper pads 244a through the first circuit plugs 232a, the first circuit lower pads 246a, and the first circuit wirings 242a.

The first power pads 248a may be disposed on the sixth surface CL1b of the second circuit insulating layer 240a. A lower surface of each of the first power pads 248a may be exposed at the second circuit insulating layer 240a, as illustrated in FIG. 3. Each of the first power pads 248a may be connected to a corresponding one of first chip through electrodes TSV1 to be described later. The first power pads 248a may be electrically connected to the first transistors TR1 through the first circuit wirings 242a, the first circuit lower pads 246a, and the first circuit plugs 232a.

The first chip through electrodes TSV1 may be inserted as a portion of the first circuit layer CL1. In detail, the first chip through electrodes TSV1 may pass through the first circuit insulating layer 230a. The first chip through electrodes TSV1 may pass through the first semiconductor substrate SS1. The first chip through electrodes TSV1 may be further inserted into the first wiring insulating layer 210a.

An upper surface of each of the first chip through electrodes TSV1 may be exposed at the first circuit insulating layer 230a, as illustrated in FIG. 3. A level of the upper surface of each of the first chip through electrodes TSV1 may be the same as that of the sixth surface CL1b of the second circuit insulating layer 240a. The upper surface of each of the first chip through electrodes TSV1 may be in contact with a corresponding one of the first power pads 248a. That is, each of the first chip through electrodes TSV1 may be connected to a corresponding one of the first power pads 248a. A lower surface of each of the first chip through electrodes TSV1 may be lower than the third surface WL1a of the first wiring insulating layer 210a. Each of the first chip through electrodes TSV1 may be in contact with a corresponding one of the first wiring patterns 212a of the first wiring layer WL1. That is, each of the first chip through electrodes TSV1 may be connected to a corresponding one of the first wiring patterns 212a of the first wiring layer WL1. Alternatively, a level of the lower surface of each of the first chip through electrodes TSV1 may be the same as that of the third surface WL1a of the first wiring insulating layer 210a. The first chip through electrodes TSV1 may include a metal material such as copper, titanium, or tungsten.

The first chip through electrodes TSV1 may be electrically connected to the first transistors TR1 through the first power pads 248a. The first chip through electrodes TSV1 may be electrically connected to the first wiring patterns 212a and the first wiring pads 214a of the first wiring layer WL1. The first chip through electrodes TSV1 may transfer a power voltage supplied from the first wiring layer WL1 to the first transistors TR1 through the first power pads 248a.

According to the concept of the present disclosure, the semiconductor package 1 may include the chip stacks SSP. The first semiconductor chip 200a of the chip stacks SSP may include the first wiring layer WL1 including the first wiring patterns 212a, the first semiconductor substrate SS1 on the first wiring layer WL1, and the first circuit layer CL1 including the first circuit wiring 242a and the first transistors TR1 on the first semiconductor substrate SS1. The first semiconductor chip 200a may include the first chip through electrodes TSV1 electrically connected to the first wiring patterns 212a and the first circuit wirings 242a. The first chip through electrodes TSV1 may transmit the power voltage supplied from the first wiring patterns 212a of the first wiring layer WL1 to the first transistors TR1 through the first circuit wirings 242a. To this end, voltage drop in the first semiconductor chip 210a may be reduced and an opening/closing time may be shortened. Accordingly, electrical characteristics of the semiconductor package 1 may be improved.

Each of the first chip through electrodes TSV1 may have a first height H1. The first height H1 may be a vertical height (i.e., a height in the third direction D3) of each of the first chip through electrodes TSV1. A vertical distance from a lower surface of the first semiconductor substrate SS1 to an upper surface of the first circuit insulating layer 230a (i.e., the distance in the third direction D3) may be a second height H2. The first height H1 may be greater than or equal to the second height H2. The first height H1 and the second height H2 may have a range of 2 μm to 50 μm.

In addition, each of the first chip through electrodes TSV1 may have the first height H1. The first height H1 may be a vertical height (i.e., a height in the third direction D3) of each of the first chip through electrodes TSV1. The first height H1 may have a range of 2 μm to 50 μm. When the first height H1 is 2 μm or less, it may be difficult to form the first wiring layer WL1. In addition, when the first height H1 exceeds 50 μm, resistance of the first chip through electrodes TSV1 may increase, and thus the voltage drop reduction function may not be properly performed. Accordingly, when the first height H1 has a range of 2 μm to 50 μm, electrical characteristics of the semiconductor package 1 may be improved.

The second semiconductor chip 200b may be provided on the first semiconductor chip 200a. The second semiconductor chip 200b may be substantially the same semiconductor chip as the first semiconductor chip 200a. That is, the second semiconductor chip 200b may include substantially the same components as the first semiconductor chip 200a.

The second semiconductor chip 200b may include a second wiring layer WL2, a second semiconductor substrate SS2, a second circuit layer CL2, and a plurality of second chip through electrodes TSV2. The second semiconductor chip 200b may be, for example, a logic chip or a memory chip such as DRAM or NAND flash.

The second wiring layer WL2 may correspond to (i.e., may be similar to) the first wiring layer WL1. The second wiring layer WL2 may include a second wiring insulating layer 210b, a plurality of second wiring patterns 212b, and a plurality of second wiring pads 214b. The second wiring insulating layer 210b, the second wiring patterns 212b, and the second wiring pads 214b may correspond to (i.e., may be similar to) the first wiring insulating layer 210a, the first wiring patterns 212a, and the first wiring pads 214a, respectively.

The second semiconductor substrate SS2 may correspond to (i.e., may be similar to) the first semiconductor substrate SS1. The second semiconductor substrate SS2 may be provided on the second wiring layer WL2.

The second circuit layer CL2 may correspond to (i.e., may be similar to) the first circuit layer CL1. The second circuit layer CL2 may be disposed on the second semiconductor substrate SS2. The second circuit layer CL2 may include second integrated circuits, third circuit insulating layer 230b, second circuit plugs 232b, fourth circuit insulating layer 240b, second circuit wirings 242b, second circuit upper pads 244b, second circuit lower pads 246b, and second power pads 248b. The second integrated circuits may include a plurality of second transistors TR2 formed on the second semiconductor substrate SS2. When the second transistors TR2 are MOSFETs, the second transistors TR2 may include a second gate structure GS2, a second source/drain S/D2, and a second device isolation layer ST2. The second gate structure GS2, the second source/drain S/D2, and the second device isolation layer ST2 may be correspond to (i.e., may be similar to) the first gate structure GS1, the first source/drain S/D1, and the first device isolation layer ST1, respectively. The second integrated circuits, the third circuit insulating layer 230b, the second circuit plugs 232b, the fourth circuit insulating layer 240b, the second circuit wirings 242b, the second circuit top pads 244b, the second circuit lower pads 246b, and the second power pads 248b may correspond to (i.e., may be similar to) the first integrated circuits, the first circuit insulating layer 230a, the first circuit plugs 232a, and the second circuit insulating layer 240a, the first circuit wirings 242a, the first circuit upper pads 244a, the second circuit lower pads 246a, and the first power pads 248a, respectively.

The second chip through electrodes TSV2 may correspond to (i.e., may be similar to) the first chip through electrodes TSV1. The second chip through electrodes TSV2 may be inserted as a portion of the second circuit layer CL2. In detail, the second chip through electrodes TSV2 may pass through the third circuit insulating layer 230b. The second chip through electrodes TSV2 may pass through the second semiconductor substrate SS2. The second chip through electrodes TSV2 may be further inserted into the second wiring insulating layer 210b.

The second chip through electrodes TSV2 may be electrically connected to the second transistors TR2 through the second power pads 248b. The second chip through electrodes TSV2 may be electrically connected to the second wiring patterns 212b and the second wiring pads 214b of the second wiring layer WL2. The second chip through electrodes TSV2 may transfer a power voltage supplied from the second wiring layer WL2 to the second transistors TR2 through the second power pads 248b.

The second connection terminals 320 may be interposed between the first semiconductor chip 200a and the second semiconductor chip 200b. Each of the second connection terminals 320 may be in contact with a corresponding one of the first circuit upper pads 244a of the first semiconductor chip 200a and a corresponding one of the second wiring pads 214b of the second semiconductor chip 200b. The second connection terminals 320 may be electrically connected to the first circuit upper pads 244a and the second wiring pads 214b. That is, the first semiconductor chip 200a and the second semiconductor chip 200b may be electrically connected through the second connection terminals 320. The second connection terminals 320 may include at least one of a solder, a pillar, and a bump. The second connection terminals 320 may include a conductive material such as tin (Sn) or silver (Ag).

The second underfill pattern 330 may be interposed between the first semiconductor chip 200a and the second semiconductor chip 200b. The second underfill pattern 330 may completely seal side surfaces of each of the second connection terminals 320. A side surface of the second underfill pattern 330 may be aligned with a side surface of the first semiconductor chip 200a and a side surface of the second semiconductor chip 200b. The second underfill pattern 330 may include insulating resin.

The first semiconductor chip 200a and the second semiconductor chip 200b may include the same type of chips. For example, when the first semiconductor chip 200a is a memory chip, the second semiconductor chip 200b may also be a memory chip. For example, when the first semiconductor chip 200a is a logic chip, the second semiconductor chip 200b may also be a logic chip. The side surface of the first semiconductor chip 200a and the side surface of the second semiconductor chip 200b may be aligned in parallel with each other, as illustrated in FIG. 3. A width of the first semiconductor chip 200a in the first direction D1 may be substantially the same as a width of the second semiconductor chip 200b in the first direction D1. In this specification, the term “substantially the same” means a concept that includes differences due to limitations in process capability. A thickness of the first semiconductor chip 200a may be substantially the same as that of the second semiconductor chip 200b.

When the width of the first semiconductor chip 200a in the first direction D1 is different from the width of the second semiconductor chip 200b in the first direction D1, an additional process is required to mount the second semiconductor chip 200b on the first semiconductor chip 200a. On the other hand, according to the concept of the present invention, the width of the first semiconductor chip 200a in the first direction D1 and the width of the second semiconductor chip 200b in the first direction D1 may be substantially equal to each other. To this end, a manufacturing process of the chip stacks SSP may be shortened, and thus a manufacturing cost of the semiconductor package 1 may be reduced.

According to the concept of the present disclosure, the thickness of the first semiconductor chip 200a and the thickness of the second semiconductor chip 200b may be substantially equal to each other. Therefore, lengths of the first chip through electrode TSV1 and the length of the second chip through electrode TSV2 may be substantially the same, and thus a resistance of the first chip through electrode TSV1 may be substantially equal to a resistance of the second chip through electrode TSV2. Therefore, a difference in magnitude between a voltage transmitted to the first transistors TR1 through the first chip through electrode TSV1 and a voltage transmitted through the second chip through electrode TSV2 to the second transistors TR2 may be reduced, thereby stably delivering power voltage. To this end, electrical characteristics of the semiconductor package 1 may be improved.

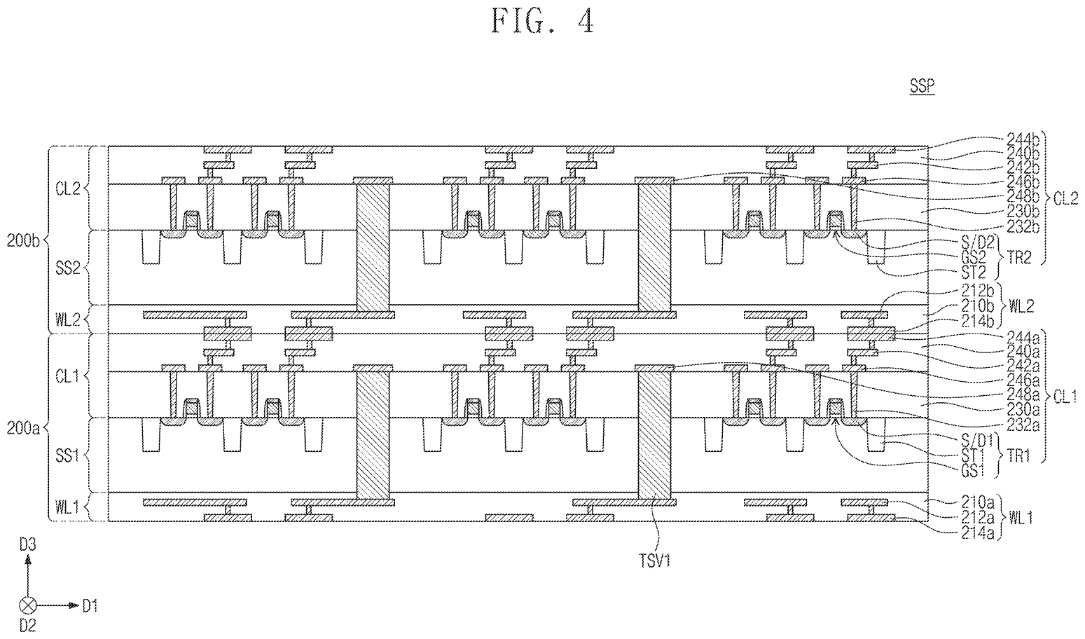

FIG. 4 is an enlarged view of chip stacks according to other embodiments of the present disclosure. Except for the description below, contents overlapping with those described with reference to FIG. 3 will be omitted.

Referring to FIG. 4, the second connection terminals 320 and the second underfill pattern 330 in the chip stacks SSP of FIG. 3 may be omitted. That is, according to an embodiment, the chip stacks SSP may not include the second connection terminals 320 and the second underfill pattern 330. The first circuit upper pads 244a of the first semiconductor chip 220a and the second wiring pads 214b of the second semiconductor chip 220b may be in contact with each other. The first circuit upper pads 244a and the second wiring pads 214b may be integrally formed with each other. An upper surface of the second circuit insulating layer 240a and a lower surface of the second wiring insulating layer 210b may be in contact with each other. That is, the first semiconductor chip 200a and the second semiconductor chip 200b may be connected by hybrid bonding.

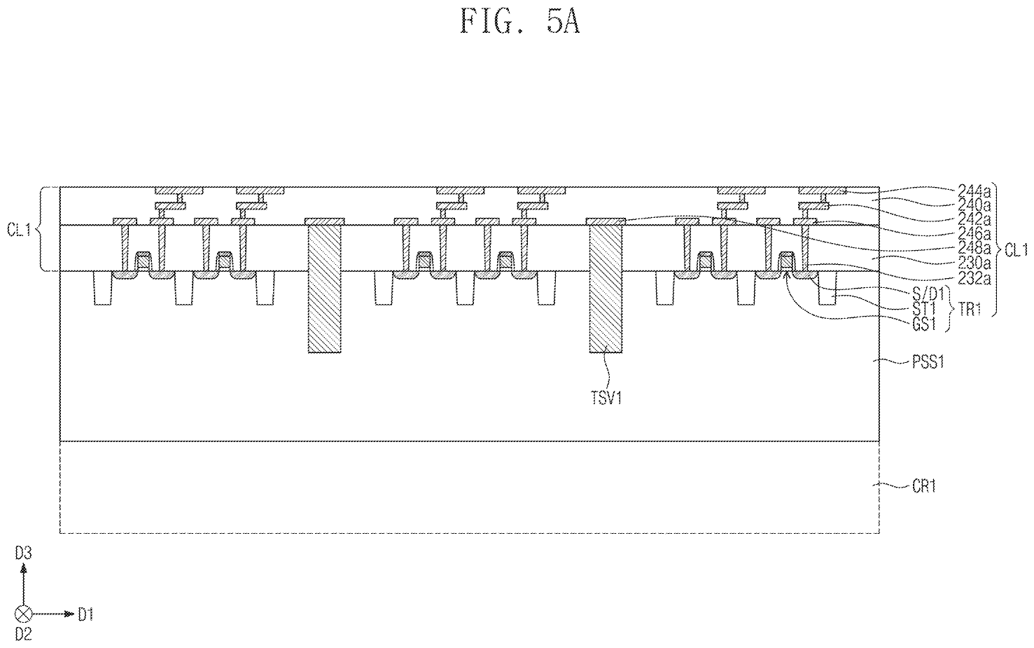

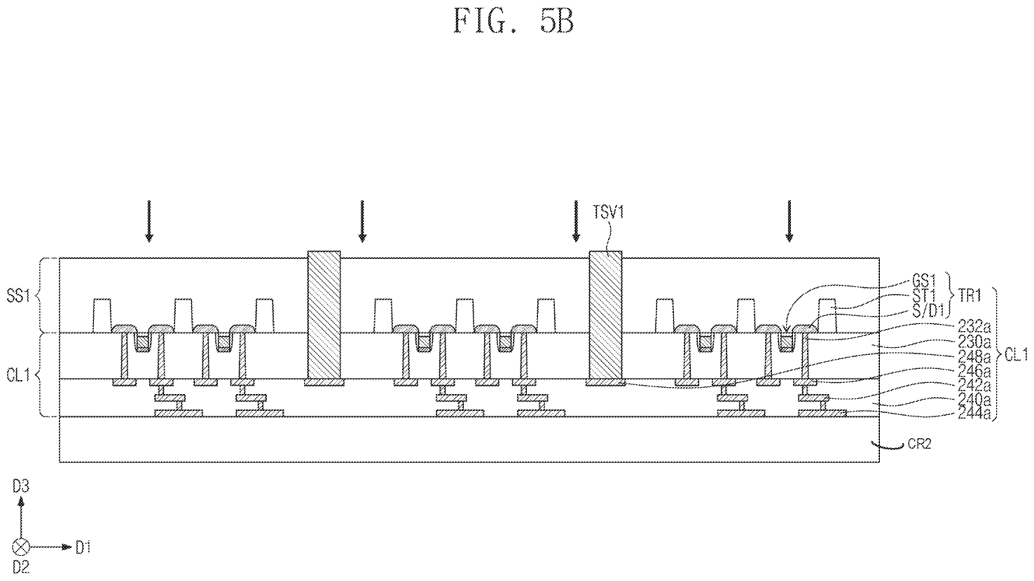

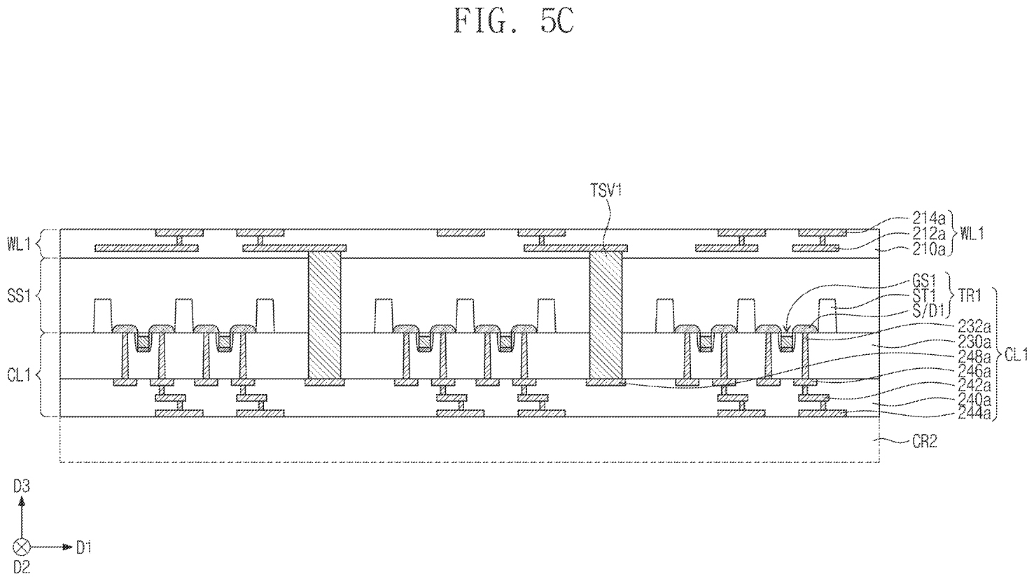

FIGS. 5A to 5C are cross-sectional views illustrating a method of manufacturing chip stacks according to embodiments of the present disclosure.

Referring to FIG. 5A, a first circuit layer CL1 and first chip through electrodes TSV1 may be formed on a first preliminary semiconductor substrate PSS1 attached to a first carrier substrate CR1. The first carrier substrate CR1 may be a resin substrate or a glass substrate. Forming the first circuit layer CL1 may include forming a plurality of first transistors TR1, a first circuit insulating layer 230a, a plurality of first circuit plugs 232a, a second circuit insulating layer 240a, a first circuit wiring 242a, a plurality of first circuit upper pads 244a, a plurality of first circuit lower pads 246a, and a plurality of first power pads 248a.

Each of the first transistors TR1 may include a first gate structure GS1, a first source/drain S/D1, and a first device isolation layer ST1. The first gate structure GS1 may be formed by CVD and PVD processes. The first source/drain S/D1 may be formed by doping impurities on the first preliminary semiconductor substrate PSS1. The first device isolation layer ST1 may be formed by performing a photolithography process, an etching process, and a deposition process. The second circuit insulating layer 240a, the first circuit wiring 242a, the first circuit upper pads 244a, the first circuit lower pads 246a, and the first power pads 248a may be formed by repeatedly performing a photolithography process, an etching process, a plating process, and the like. The plurality of first chip stack electrodes TSV1 may be formed by performing a photolithography process, an etching process, and a deposition process. A lower surface of each of the first chip stack electrodes TSV1 may be higher than a lower surface of the first preliminary semiconductor substrate PSS1.

Referring to FIG. 5B, the first carrier substrate CR1 may be removed, and the first preliminary semiconductor substrate PSS1 and the first circuit layer CL1 fabricated in FIG. 5A may be inverted and attached to a second carrier substrate CR2. In this case, a lower surface of the first preliminary semiconductor substrate PSS1 in FIG. 5A may be the same as an upper surface of the first preliminary semiconductor substrate PSS1 in FIG. 5B. The second carrier substrate CR2 may be a resin substrate or a glass substrate.

A chemical mechanical polishing (CMP) process, an etch-back process, or a combination thereof may be performed on the upper surface of the first preliminary semiconductor substrate PSS1 to remove a portion of the first preliminary semiconductor substrate PSS1, and a first semiconductor substrate SS1 may be formed. A portion of each of the first chip stack electrodes TSV1 may be exposed by the first semiconductor substrate SS1. One end of each of the first chip stack electrodes TSV1 may protrude from the first semiconductor substrate SS1.

Referring to FIG. 5C, a first wiring layer WL1 may be formed on the first semiconductor substrate SS1. Forming the first wiring layer WL1 may include forming a first wiring insulating layer 210a, forming a plurality of first wiring patterns 212a, and forming a plurality of first wiring pads 214a. The first wiring insulating layer 210a, the first wiring patterns 212a, and the first wiring pads 214a may be formed by repeatedly performing a photolithography process, an etching process, a plating process, or the like. The second carrier substrate CR2 may be removed. As a result, the first semiconductor chip 200a may be formed.

Referring back to FIG. 3, the second semiconductor chip 200b may be formed in the same manner as the first semiconductor chip 200a. After a second connection terminal 320 may be formed on the first circuit upper pads 244a of the first semiconductor chip 200a, the second semiconductor chip 200b may be mounted on the first semiconductor chip 200a.

A second underfill pattern 330 may be formed between the first semiconductor chip 200a and the second semiconductor chip 200b. The second underfill pattern 330 may be formed through processes such as inputting and curing of an underfill material. As a result, chip stacks SSP may be formed.

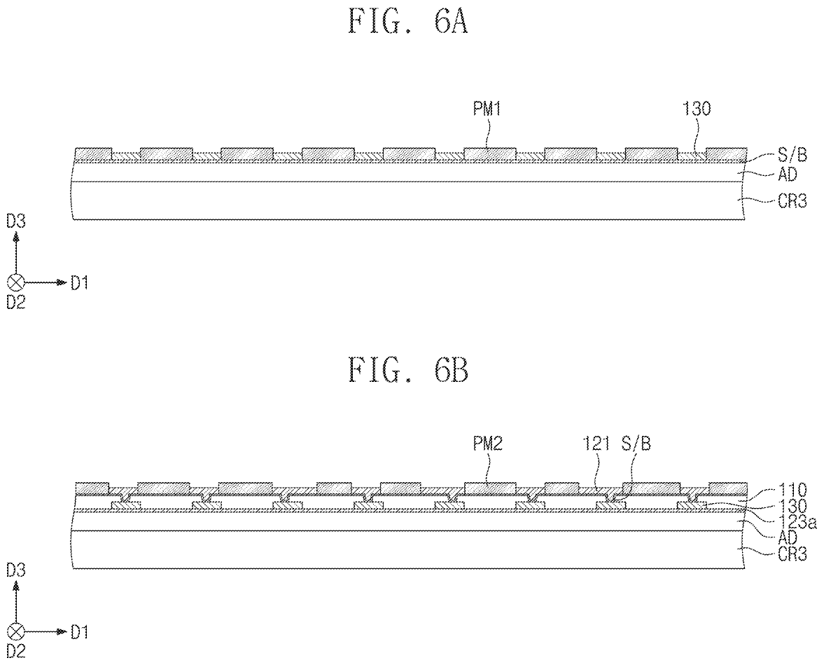

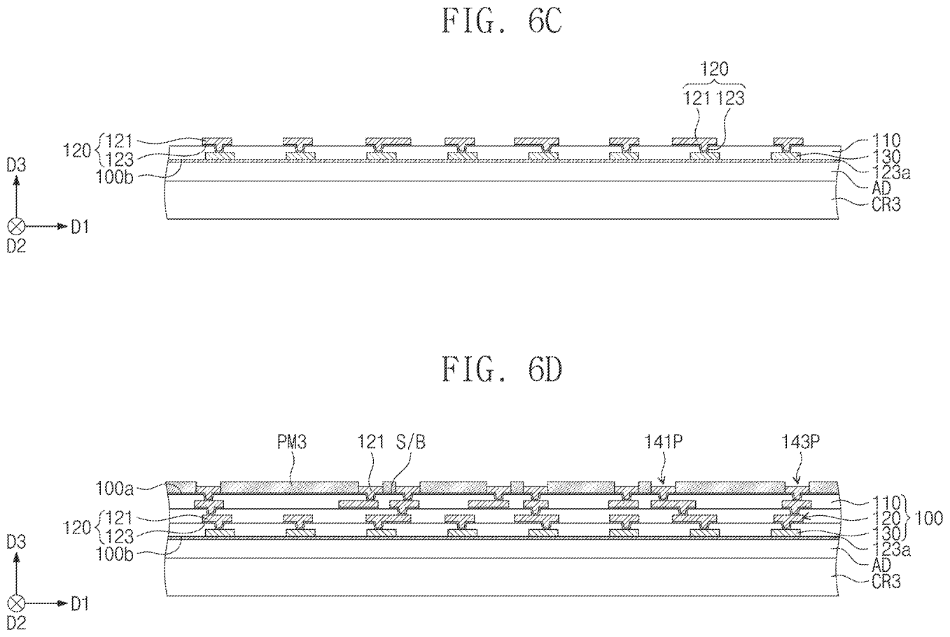

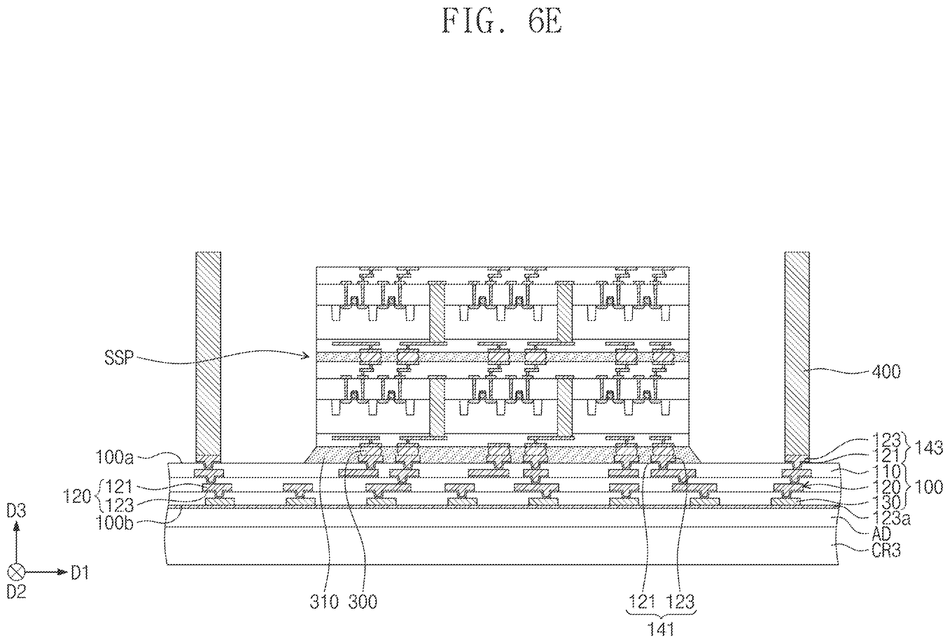

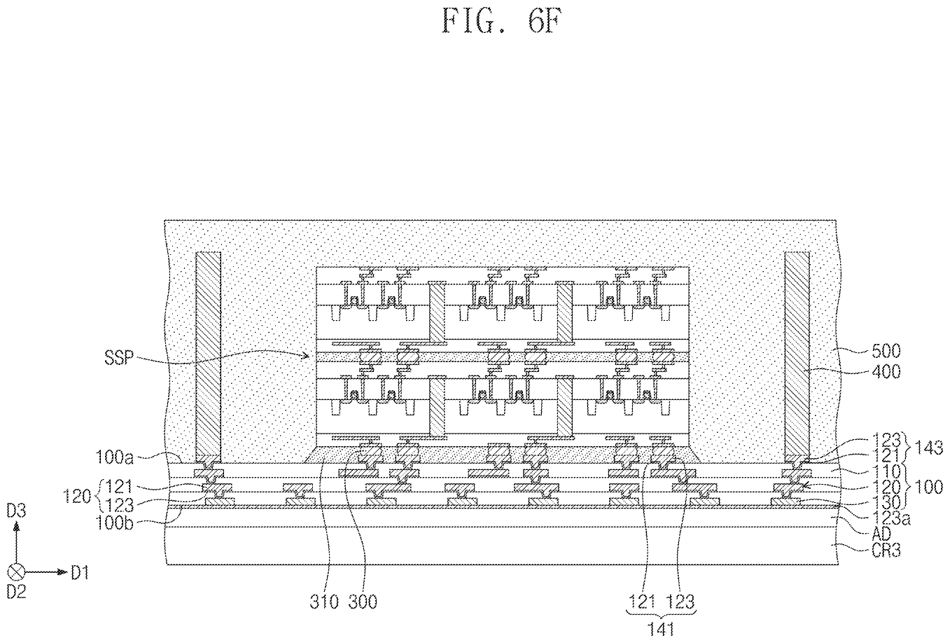

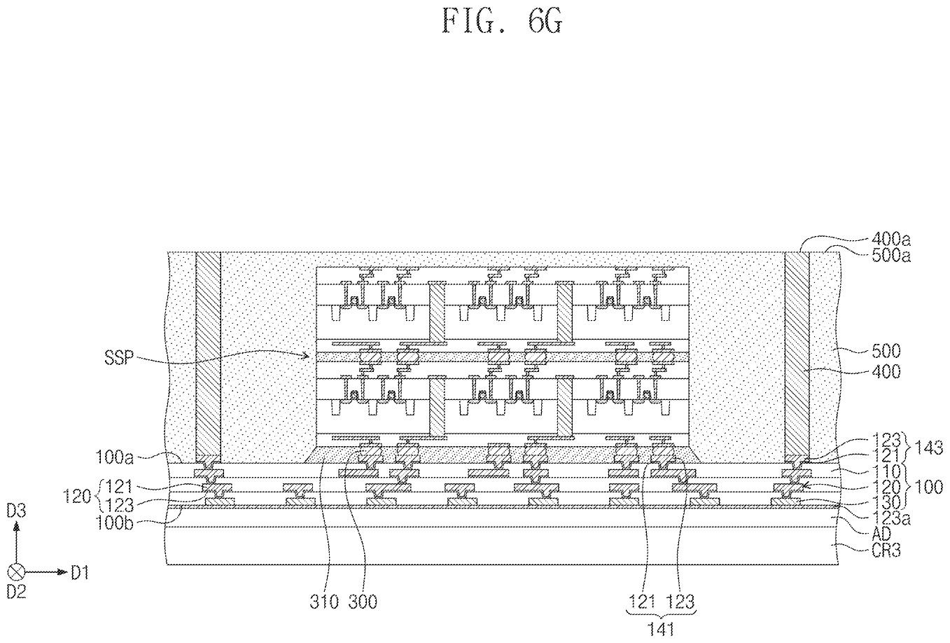

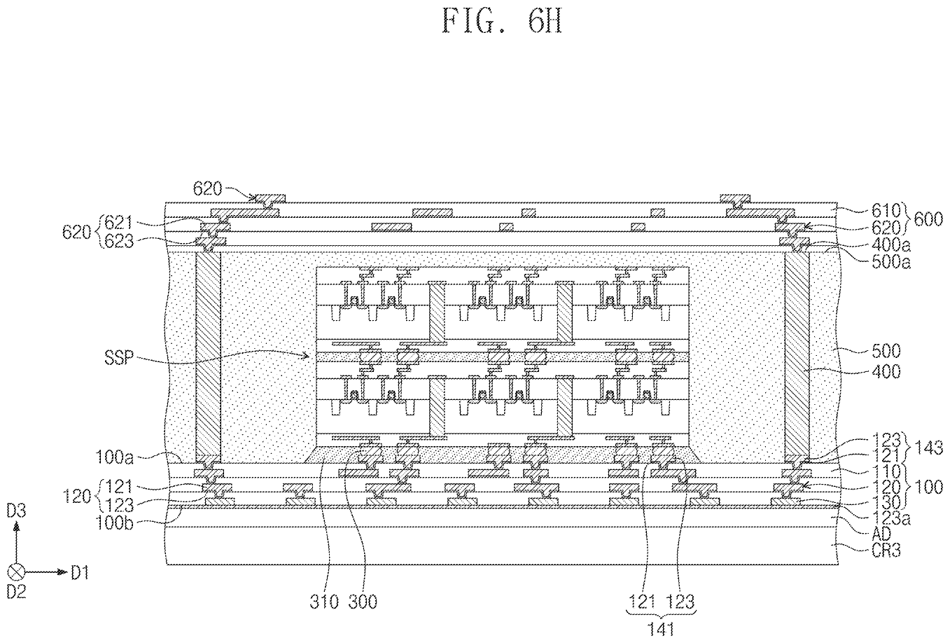

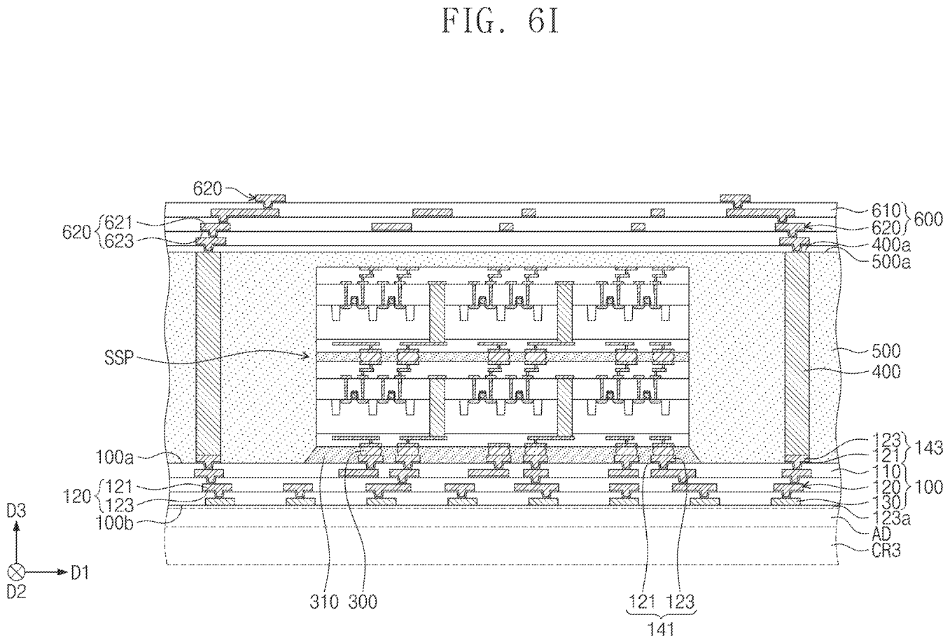

FIGS. 6A to 6I are cross-sectional views illustrating a method of manufacturing a semiconductor package according to embodiments of the present disclosure.

Referring to FIG. 6A, a third carrier substrate CR3 having an adhesive layer AD formed thereon may be provided. A seed/barrier layer S/B may be formed on the third carrier substrate CR3 to cover an upper surface of the adhesive layer AD. The seed/barrier layer S/B may be formed by a deposition process. For example, the seed/barrier layer S/B may include copper and titanium. The adhesive layer AD may attach the seed/barrier layer S/B to the upper surface of the third carrier substrate CR3.

A first photo mask pattern PM1 may be formed on an upper surface of the seed/barrier layer S/B. The first photomask pattern PM1 may include an opening defining a space where the under bump pattern 130 is to be formed. The first photomask pattern PM1 may be formed through a process of forming a photoresist layer, exposure, and development. A portion of the seed/barrier layer S/B may be exposed by the first photomask pattern PM1. The under bump pattern 130 may be formed by performing an electroplating process using the seed/barrier layer S/B as an electrode in the opening.

Referring to FIG. 6B, the first photo mask pattern PM1 may be removed. Subsequently, a first insulating layer 110 covering the under bump pattern 130 may be formed. The first insulating layer 110 may be formed by a process such as spin coating and then patterned to have an opening exposing at least a portion of an upper surface of the under bump pattern 130 by an exposure and development process. Subsequently, a curing process of the first insulating layer 110 may be performed. A seed/barrier layer S/B may be formed on the first insulating layer 110 again. A second photo mask pattern PM2 including openings may be formed on the seed/barrier layer S/B. A first conductive pattern 121 may be formed on the seed/barrier layer S/B by performing an electroplating process using the seed/barrier layer S/B as an electrode.

Referring to FIG. 6C, the second photo mask pattern PM2 may be removed. Subsequently, the seed/barrier layer S/B in the region exposed from the first conductive pattern 121 may be removed to form a first seed/barrier pattern 123. A first redistribution pattern 120 including a first conductive pattern 121 and a first seed/barrier pattern 123 may be formed.

Referring to FIG. 6D, in the same way as the method in which the first insulating layer 110 and the first redistribution patterns 120 are formed, the first insulating layers 110 and the first redistribution patterns 120 may be sequentially and repeatedly stacked. After an uppermost first redistribution patterns 120 are stacked, a first insulating layer 110 exposing a portion of an uppermost one of the first redistribution patterns 120 may be formed. The uppermost first insulating layer 110 may undergo spin coating, exposure, development, and curing processes. A first surface 100a of the uppermost first insulating layer 110 is identical to the first surface 100a of the first substrate 100. A seed/barrier layer S/B may be formed on the uppermost first insulating layer 110. Subsequently, a third photo mask pattern PM3 including openings may be formed. A first conductive pattern 121 may be formed on the seed/barrier layer S/B by an electroplating method using the seed/barrier layer S/B as an electrode. The seed/barrier layer S/B and the first conductive patterns 121 may constitute a first preliminary upper pad 141P and a second preliminary upper pad 143P.

Referring to FIG. 6E, a conductive post 400 may be formed on the second preliminary upper pad 143P by performing an electroplating process using the first conductive pattern 121 of the second preliminary upper pad 143P as an electrode. The third photo mask pattern PM3 may be removed. Subsequently, the seed/barrier layer S/B of the region exposed by the first conductive patterns 121 of the first preliminary upper pad 141P and the second preliminary upper pad 143 may be removed to form a first seed/barrier pattern 123. As a result, the first preliminary upper pad 141P and the second preliminary upper pad 143P may be formed as a first upper pad 141 and a second upper pad 143, respectively. Simultaneously, the first substrate 100 may also be formed.

The chip stacks SSP manufactured by the process described in FIGS. 5A to 5C may be mounted on the first substrate 100. The chip stacks SSP may be mounted on the first substrate 100 such that the first wiring layer WL1 of the first semiconductor chip 200a faces the first substrate 100. A process of disposing the chip stacks SSP on the first substrate 100 may use a thermal compression process. First connection terminals 300 attached to the first wiring pads 214a may be attached to the first upper pads 141, respectively. A first underfill pattern 310 may be formed through processes such as inputting and curing of an underfill material. According to some embodiments, the forming of the first underfill pattern 310 may be omitted.

Referring to FIG. 6F, a first mold structure 500 may be formed to cover the first surface 100a of the first substrate 100, upper and side surfaces of the chip stacks SSP, and upper and side surfaces of the conductive posts 400. The first mold structure 500 may be formed through a process of inputting and curing a molding material in a molten state. The molding material may include, for example, a molten epoxy molding compound (EMC).

Referring to FIG. 6G, a planarization process may be performed on the first mold structure 500. The planarization process may be performed until the upper surface 400a of the conductive post 400 is exposed. As a result of the planarization process, an upper surface 500a of the first mold structure 500 may be coplanar with an upper surface 400a of the conductive post 400.

Referring to FIG. 6H, a second substrate 600 may be formed on the first mold structure 500 and the conductive posts 400. The forming of the second substrate 600 may be formed in substantially the same manner as the forming of the first substrate 100 described above. A second redistribution pattern 620 may be formed to be connected to the conductive posts 400.

Referring to FIG. 6I, a singulation process may be performed in a third direction D3 along a sawing line SL. Subsequently, the third carrier substrate CR3, the adhesive layer AD, and the seed/barrier layer 123a may be removed. The removing of the seed/barrier layer 123a may be performed by an etching process. As the seed/barrier layer 123a is removed, the under bump patterns 130 may be exposed.

Referring back to FIG. 2, a lower package LPKG may be formed by forming external connection terminals 900 on the exposed under bump patterns 130. Subsequently, a upper package UPKG may be mounted on the lower package LPKG. Accordingly, the semiconductor package 1 may be manufactured.

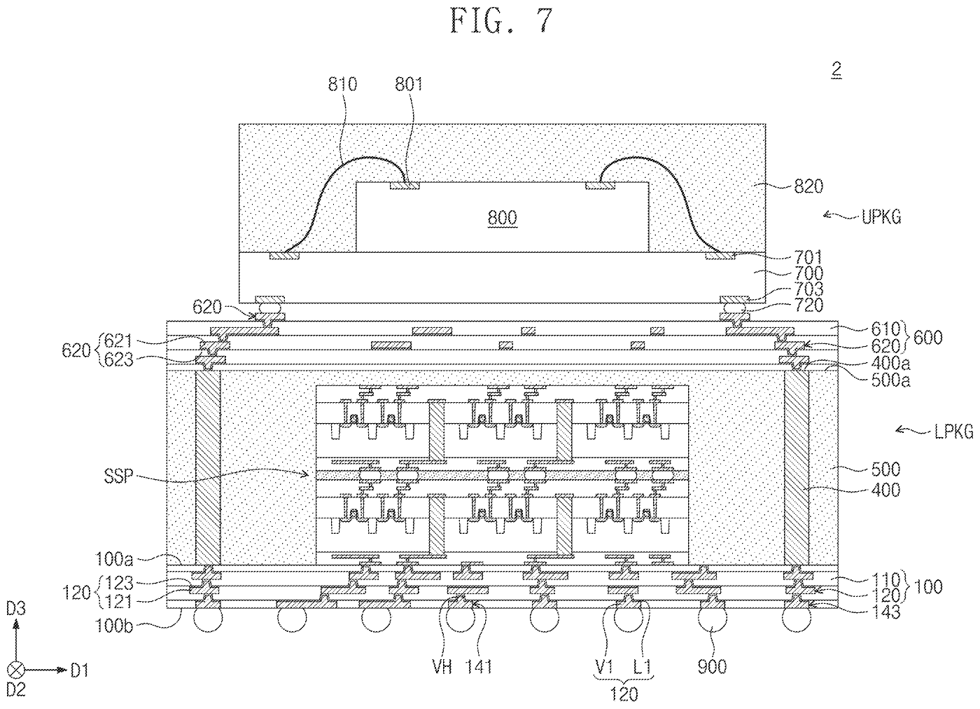

FIG. 7 is a cross-sectional view of a semiconductor package according to other embodiments of the present disclosure. Except for the description below, contents overlapping those described with reference to FIGS. 1 and 2 will be omitted.

Referring to FIGS. 3 and 7, a plurality of chip stacks SSP of the semiconductor package 2 may be in direct contact with the first substrate 100. In this case, the first connection terminal 300 and the first underfill pattern 310 in FIG. 2 may be omitted.

The first substrate 100 may include a plurality of first insulating layers 110, a plurality of first redistribution patterns 120, a plurality of first upper pads 141, and a plurality of second upper pads 143. The first redistribution patterns 120 may include a first conductive pattern 121 and a first seed/barrier pattern 123. The first upper pads 141 and the second upper pads 143 may also be referred to as first lower pads 141 and second lower pads 143, respectively. However, the first substrate 100 may not include the under bump patterns 130 described in FIG. 2. An uppermost first insulating layer 110 may be in direct contact with a lower surface of the first semiconductor chip 200a. In detail, the uppermost first insulating layer 110 may be in direct contact with the lower surface of the first wiring insulating layer 210a.

The first seed/barrier patterns 123 may be provided on upper surfaces of the first redistribution patterns 120, respectively. The first seed/barrier pattern 123 in the uppermost first insulating layer 110 may be in contact with the first wiring pads 214a provided on the lower surface of the first wiring insulating layer 210a. For example, the via part V1 of each of the uppermost first redistribution patterns 120 may vertically overlap the first wiring pads 214a.

External connection terminals 900 may be disposed on lower surfaces. The first lower pads 141 and the second lower pads 143 may function as pads of the external connection terminals 900.

The semiconductor package 2 may be manufactured by a chip-first process, but is not limited thereto.

The semiconductor package according to the concept of the present disclosure may include the chip stacks including the semiconductor chip. The semiconductor chip may include the wiring layer including the wiring patterns, the semiconductor substrate on the wiring layer, and the circuit layer including circuit wirings and transistors on the semiconductor substrate. The semiconductor chip may further include the chip through electrodes electrically connected to the wiring patterns and the circuit wirings. The chip through electrodes may transfer the power voltage supplied from the wiring patterns of the wiring layer to the transistors through the circuit wirings. To this end, the voltage drop in the semiconductor chip may be reduced and the opening/closing time may be shortened. Accordingly, the electrical characteristics of the semiconductor package may be improved.

In addition, the vertical height of the chip through electrode may range from 2 μm to 50 μm. When the vertical height of the chip through electrode is 2 μm or less, it may be difficult to form the wiring layer. In addition, when the vertical height of the chip through electrode exceeds 50 μm, the resistance of the chip through electrode may become high, and thus the voltage drop reduction function may not be properly performed. Accordingly, when the vertical height of the chip through electrode is in the range of 2 μm to 50 μm, the electrical characteristics of the semiconductor package may be improved.

While embodiments are described above, a person skilled in the art may understand that many modifications and variations are made without departing from the scope of the present disclosure defined in the following claims. Accordingly, the example embodiments of the present disclosure should be considered in all respects as illustrative and not restrictive, with the scope of the present disclosure being indicated by the appended claims.

What is claimed is:

1. A semiconductor package comprising:
a lower package; and
an upper package on the lower package,
wherein the lower package comprises:
a first substrate;
a plurality of chip stacks on the first substrate;
a first mold structure on the first substrate and covering at least a portion of the plurality of chip stacks; and
a second substrate on the first mold structure,
wherein the plurality of chip stacks comprise:
a first semiconductor chip; and
a second semiconductor chip on the first semiconductor chip,
wherein the first semiconductor chip comprises:
a first semiconductor substrate;
a first wiring layer adjacent the first semiconductor substrate, wherein the first wiring layer comprises a plurality of wiring patterns;
a first circuit layer on the first semiconductor substrate, wherein the first circuit layer comprises a transistor and a plurality of circuit wirings connected to the transistor; and
a chip through electrode penetrating at least a portion of the first circuit layer and the first semiconductor substrate,
wherein a height of the chip through electrode ranges from 2 μm to 50 μm,
wherein a width of the first semiconductor chip is substantially equal to a width of the second semiconductor chip, and
wherein the chip through electrode is connected to the plurality of wiring patterns and the plurality of circuit wirings.

2. The semiconductor package of claim 1, wherein the chip through electrode extends into an upper portion of the first wiring layer, and
wherein the chip through electrode is in direct contact with an uppermost one of the plurality of wiring patterns.

3. The semiconductor package of claim 1, wherein the first circuit layer further comprises a power pad on the chip through electrode in the first circuit layer,
wherein the power pad is connected to the chip through electrode and the plurality of circuit wirings.

4. The semiconductor package of claim 1, wherein the first circuit layer comprises:
a first circuit insulating layer covering the transistor;
a circuit plug penetrating the first circuit insulating layer and connected to the transistor;
a second circuit insulating layer on the first circuit insulating layer and covering the plurality of circuit wirings;
a circuit upper pad on an upper surface of the second circuit insulating layer; and
a circuit lower pad on a lower surface of the second circuit insulating layer,
wherein the circuit lower pad is in contact with the circuit plug.

5. The semiconductor package of claim 1, wherein the first substrate comprises an under bump pattern on a lower surface thereof and an external connection terminal on a lower surface of the under bump pattern,
wherein the external connection terminal is connected to the plurality of chip stacks through the under bump pattern.

6. The semiconductor package of claim 1, wherein the first circuit layer further comprises a circuit upper pad on an upper surface of the first circuit layer,
wherein the second semiconductor chip comprises:
a second semiconductor substrate;
a second wiring layer adjacent the second semiconductor substrate; and
a second circuit layer on the second semiconductor substrate,
wherein the second wiring layer comprises a wiring pad on a lower surface of the second wiring layer,
wherein the plurality of chip stacks further comprise a connection terminal between the first semiconductor chip and the second semiconductor chip, and
wherein the connection terminal is in contact with the circuit upper pad and the wiring pad.

7. The semiconductor package of claim 1, wherein the first wiring layer further comprises a wiring pad on a lower surface thereof,
wherein the first substrate comprises:
a plurality of insulating layers;
a plurality of redistribution patterns in the plurality of insulating layers; and
an upper pad on an uppermost one of the plurality of redistribution patterns,
wherein the lower package further comprises a connection terminal interposed between the plurality of chip stacks and the upper pad, and
wherein the connection terminal is in contact with the wiring pad and the upper pad.

8. The semiconductor package of claim 1, wherein the first substrate comprises:
a plurality of insulating layers;
a plurality of redistribution patterns in the plurality of insulating layers; and
an upper pad provided on an uppermost one of the plurality of redistribution patterns,
wherein the lower package is provided on the first substrate and further comprises a conductive post spaced apart from the plurality of chip stacks in a first direction, and
wherein the conductive post contacts the upper pad.

9. The semiconductor package of claim 1, wherein the upper package comprises:
a third semiconductor chip on the second substrate;
a package substrate interposed between the second substrate and the third semiconductor chip; and
a second mold structure covering at least a portion of an upper surface of the package substrate and the third semiconductor chip.

10. The semiconductor package of claim 1, wherein the first substrate comprises:
a plurality of insulating layers;
a plurality of redistribution patterns in the plurality of insulating layers; and
a plurality of seed/barrier patterns respectively provided on upper surfaces of the plurality of redistribution patterns,
wherein the first wiring layer comprises a plurality of wiring pads on a lower surface of the first wiring layer, and
wherein an uppermost one of the plurality of insulating layers and an uppermost one of the plurality of seed/barrier patterns are in contact with the plurality of wiring pads.

11. The semiconductor package of claim 10, wherein the lower package is on the first substrate and further comprises a conductive post spaced apart from the plurality of chip stacks in a first direction,
wherein the conductive post is in contact with an uppermost one of the plurality of seed/barrier patterns.

12. The semiconductor package of claim 1, wherein a side surface of the first semiconductor chip and a side surface of the second semiconductor chip are aligned parallel to each other.

13. The semiconductor package of claim 1, wherein a side surface of the first semiconductor chip and a side surface of the second semiconductor chip are in contact with a first mold structure.

14. A semiconductor package comprising:
a first semiconductor chip; and
a second semiconductor chip on the first semiconductor chip,
wherein the first semiconductor chip comprises:
a first wiring layer comprising a plurality of first wiring patterns;
a first circuit layer on the first wiring layer, wherein the first circuit layer comprises a plurality of first transistors, a plurality of first circuit wirings connected to the plurality of first transistors, a plurality of first power pads connected to the plurality of first transistors, and a plurality of circuit upper pads on the first circuit layer;
a first semiconductor substrate interposed between the first wiring layer and the first circuit layer; and
a first chip through electrode penetrating the first semiconductor substrate and connected to the plurality of first wiring patterns and the plurality of first power pads,
wherein the second semiconductor chip comprises:
a second semiconductor substrate;
a second wiring layer adjacent the second semiconductor substrate, the second wiring layer comprising a plurality of wiring pads on a lower surface of the second wiring layer, and a plurality of second wiring patterns connected to the plurality of wiring pads;
a second circuit layer on the second semiconductor substrate, the second circuit layer comprising a plurality of second transistors, a plurality of second circuit wirings connected to the plurality of second transistors, and a plurality of second power pads; and
a second chip through electrode penetrating the second semiconductor substrate and connected to the plurality of second wiring patterns and to the plurality of second power pads,
wherein the plurality of circuit upper pads and the plurality of wiring pads are in direct contact with each other,
wherein a thickness of the first semiconductor chip is substantially equal to a thickness of the second semiconductor chip.

15. The semiconductor package of claim 14, wherein the first chip through electrode extends into the first wiring layer,
wherein the second chip through electrode extends into the second wiring layer, and
wherein the first chip through electrode and the second chip through electrode are in direct contact with the plurality of first wiring patterns and the plurality of second wiring patterns, respectively.

16. The semiconductor package of claim 14, wherein the first chip through electrode has a first height,
wherein the second chip through electrode has a second height, and
wherein the first height and the second height each have a range of 2 μm to 50 μm.

17. The semiconductor package of claim 14, wherein the first chip through electrode has a first height,
wherein a distance from an upper surface of the first wiring layer to an upper surface of the first chip through electrode is a second height,
wherein the first height is greater than or equal to the second height, and
wherein the first height and the second height each have a range of 2 μm to 50 μm.

18. The semiconductor package of claim 14, wherein the first wiring layer further comprises a first wiring insulating layer covering the plurality of first wiring patterns,
wherein the second wiring layer further comprises a second wiring insulating layer covering the plurality of second wiring patterns, and
wherein the first wiring insulating layer and the second wiring insulating layer comprise at least one of silicon oxide, silicon nitride, and silicon oxynitride.

19. A semiconductor package comprising:
a first substrate;
a plurality of chip stacks on the first substrate;
a conductive post on the first substrate and spaced apart from the plurality of chip stacks in a first direction;
a mold structure covering the conductive post and the plurality of chip stacks; and
a second substrate on the mold structure,
wherein the plurality of chip stacks comprise a first semiconductor chip and a second semiconductor chip on the first semiconductor chip,
wherein the first semiconductor chip comprises:
a wiring layer;
a circuit layer on the wiring layer;
a semiconductor substrate interposed between the wiring layer and the circuit layer; and
a chip through electrode penetrating the semiconductor substrate,
wherein the wiring layer comprises:
a wiring insulation layer; and
a plurality of wiring patterns in the wiring insulating layer,
wherein the circuit layer comprises:
a first circuit insulating layer;
a plurality of transistors in the first circuit insulating layer;
a second circuit insulating layer on the first circuit insulating layer;
a plurality of first circuit wirings in the second circuit insulating layer; and
a power pad on a lower surface of the second circuit insulating layer, wherein the power pad contacts the chip through electrode,
wherein the chip through electrode penetrates the first circuit insulating layer,
wherein the chip through electrode has a first height,
wherein a vertical height from an upper surface of the first circuit insulating layer to an upper surface of the wiring insulating layer is a second height, and
wherein the first height has a range of 2 μm to 50 μm.

20. The semiconductor package of claim 19, wherein the first height is greater than or equal to the second height, and
wherein the second height has a range of 2 μm to 50 μm.
